(19) United States
(12) Patent Application Publication
(10) Pub. No.: US 2021/0362602 A1
(43) Pub. Date: Nov. 25, 2021

(54) CONTROL SYSTEM FOR A VEHICLE

(71) Applicant: IEE INTERNATIONAL ELECTRONICS & ENGINEERING S.A., ECHTERNACH (LU)

(72) Inventors: Baptiste ANTI, Hettange-Grande (FR); Cerronne CATHEY, Pontiac, MI (US); Hans-Peter BEISE, Perl (DE); Jan LIPTAK, Vlachovo (SK)

(21) Appl. No.: 17/059,693

(22) PCT Filed: May 28, 2019
(86) PCT No.: PCT/EP2019/063751

§ 371 Date: Nov. 30, 2020

(30) Foreign Application Priority Data
May 31, 2018 (LU) LU100816

(51) Int. Cl. B60K 37/06; B62D 1/04; H03K 17/955; G06F 3/044

(52) U.S. Cl. CPC B60K 37/06; B62D 1/046; B60K 2370/146; G06F 3/044; B60K 2370/143; H03K 17/955

(57) ABSTRACT

A control system for a vehicle includes: first electrode and second electrodes; at least one sensor electrode disposed on an vehicle component with a surface accessible to a user, the sensor electrode being adapted to generate an electric field above the surface so that a capacitance of the sensor electrode depends on a position of a body part of a user with respect to the vehicle component; and a control unit connected to the sensor electrode and adapted to: identify at least one gesture, corresponding to a motion of the body part with respect to the vehicle component, based on the capacitance of the sensor electrode; identify a control signal that corresponds to the gesture; and output the control signal. The sensor electrode has a first portion and a second portion wherein the capacitance depends on whether the body part is disposed adjacent the first portion or the second portion.

### TECHNICAL FIELD

The invention generally relates to a control system for a vehicle and more specifically to a control system configured to control one or more functions of the vehicle according to an input by a user.

### BACKGROUND

In modern vehicles, there is an increasing number of vehicle functions that can be controlled by the driver (or a passenger), e.g. pertaining to an infotainment system, and air conditioning system or other vehicle systems. For safety reasons, the driver of a vehicle should constantly keep his hands on the steering wheel. Therefore, in order to allow control of the various vehicle functions, many control devices, like switches and buttons, are integrated directly on the steering wheel. However, as the number of control devices increases, the steering wheel becomes overloaded and its usage becomes inconvenient and unnatural. Therefore, the driver often has to release his natural grip on the steering wheel in order to operate the respective control device.

Presently used control devices also require a relatively large building space and cannot be integrated e.g. into the rim of the steering wheel. Likewise, they could impair the handling of the steering wheel during normal steering operation. Similar problems exist with other vehicle components, where it is hardly possible to integrate control devices in an ergonomic way. It would also be desirable to increase the versatility of the control means, so that a single control means could be used to input different commands.

### SUMMARY

It is thus an object of the present invention to provide ergonomic and versatile control means for a user of a vehicle that allow for easy integration into various vehicle components.

This object may be achieved by the invention according to claim 1.

In accordance with one aspect of the invention there is provided a control system for a vehicle. The vehicle is normally a land vehicle like a car. However, application to sea or air vehicles is also conceivable. As will become apparent below, the control system is configured to control one or more functions of the vehicle according to an input by a user.

The control system comprises at least one sensor electrode disposed on a vehicle component with a surface accessible to a user, the sensor electrode being adapted to generate an electric field above the surface so that a capacitance of the sensor electrode depends on a position of a body part of a user with respect to the vehicle component. In this context “vehicle component” can be any component that is part of the vehicle and has at least one surface that is accessible by a user (i.e. the driver or a passenger). In particular, the vehicle component may be an interior component which is part of the vehicle interior. The at least one sensor electrode is disposed on the vehicle component, which explicitly includes the possibility that it is at least partially disposed inside the vehicle component. The at least one sensor electrode is normally disposed along the surface of the vehicle component so that it extends along the surface, or rather a portion of the surface. The sensor electrode is adapted to generate an electric field above the surface of the vehicle component, which of course implies that the sensor electrode has to be connected to an electrical power source, e.g. a voltage source, in order to generate the electric field. In particular, the electric field can be generated between the sensor electrode and a grounded structure, i.e. a structure that has (vehicle) ground potential, which is the potential of the vehicle body. Alternatively, the electric field could be generated between the sensor electrode and a structure that has a defined potential different from ground potential or even a non-defined (or floating) potential.

If an object like a body part of a user (like a hand, a finger or several fingers) enters the electric field, this influences the electric field and therefore the capacitance of the sensor electrode. Therefore, in general, the capacitance depends on the position of the at least one body part with respect to the vehicle component or with respect to the surface of the vehicle component. While reference is made to “a body part”, this normally refers to a hand or a part of a hand, in particular one or several fingers. The capacitance can be influenced by a distance of the body part from the surface of the vehicle component. Alternatively or additionally, it can be influenced by a position of the body part along the surface. It should also be understood that if the body part is far away from the sensor electrode, its position no longer has any (measurable) influence on the capacitance. Therefore, strictly speaking, the capacitance depends on the position of the at least one body part if the body part is within a detection space of the sensor electrode.

The control system further comprises a control unit that is connected to the at least one sensor electrode. The control unit may comprise several parts or modules that could be disposed in different locations and that communicate by wire or wirelessly. Normally though, all parts of the control unit are disposed in one location. At least some functions of the control unit may be software-implemented. The control unit is connected, i.e. electrically connected, to the at least one sensor electrode. In particular, the control unit may be configured to apply an electric signal to the sensor electrode, which in turn leads to the generation of the above-mentioned electric field.

The control unit is adapted to identify at least one gesture, corresponding to a motion of the body part with respect to the vehicle component, based on the capacitance of the at least one sensor electrode, to identify a control signal for the vehicle that corresponds to the gesture and to output the control signal. In other words, the control unit is adapted to detect the capacitance or a quantity representative of the capacitance, and based on this detection, the control unit can identify at least one gesture. There are several different approaches to detect the capacitance of a sensor electrode and the invention is not limited to any specific approach. For instance, the control unit could apply a constant voltage or a sinusoidal voltage to the sensor electrode and measure the current flowing into or out of the sensor electrode. It would also be possible to apply a series of pulse signals to the sensor electrode. Instead of a sinusoidal voltage, a sinusoidal current could also be employed. These are only some examples by which the capacitance can be determined either directly or implicitly. For instance, if the reactance of the sensor electrode is known at a specific frequency of a sinusoidal signal, the capacitance is implicitly known and does not have to be determined directly. If the at least one body part performs a motion with respect to the vehicle component, this causes the capacitance to change as a function of time (at least if the body part is within the detection space of the respective sensor electrode). Therefore, the motion (or at least some of its aspects) can be deduced from the time evolution of the capacitance.

According to at least some embodiments of the invention, at least one sensor electrode has a first portion and a second portion, wherein the capacitance depends on whether the body part is disposed adjacent the first portion or the second portion. Thus, it is possible to distinguish different positions of the body part along the surface of the vehicle component with a single sensor electrode. Normally, the capacitance is different for a position adjacent the first portion and adjacent the second portion due to the shape and/or size of the different portions. Certain embodiments of the at least one electrode will be discussed further below. Apart from this, it is possible to distinguish different positions by providing a plurality of sensor electrodes. If the body part is disposed adjacent (or above) one sensor electrode, the capacitance of this sensor electrode is changed significantly. If the body part moves to a position adjacent (or above) another sensor electrode, e.g. during a swiping gesture, the capacitances of these two sensor electrodes change accordingly.

In the inventive control system, certain motions are defined as gestures that correspond to control signals for the vehicle. For example, if the body part is moved in a certain direction along the surface of the vehicle component, this could be defined as a first gesture corresponding to a first control signal, while moving the body part in the opposite direction could be defined as a second gesture corresponding to a second control signal. The control unit is configured to identify at least one gesture and to identify the respective control signal. Such a control signal could e.g. be a command for an infotainment system of the vehicle, e.g. “volume up/down”, “toggle display”, “accept incoming phone call” of the like. However, the control signals could also refer to other functions of the vehicle like the air conditioning etc. After the control signal has been identified, the control signal is output by the control unit. Herein, the term “control signal” is not to be construed in a limiting way. For instance, the control signal could be an analogue signal like a voltage level. Normally, however, it is a digital signal that could be sent e.g. via a bus system in the vehicle.

The inventive control system allows for an easy and convenient way of controlling certain vehicle functions. The user (driver, passenger or other) can control these functions by certain gestures performed on or near the vehicle component. Since a sensor electrode does not need any movable parts, the mechanical setup of the respective vehicle component can be kept simple. Further, sensor electrodes do not suffer from mechanical wear or failure. Sensor electrodes can also be used in areas where no sufficient building space is available for a mechanical switch or the like.

The vehicle component could e.g. be a dashboard, a headliner, a seat belt, and armrest, an interior floor, a gear shift/gear lever or an exterior keypad, such as e.g. a handle for opening the door. Preferably, the vehicle component is a steering wheel. Since the inventive control system employs sensor electrodes that can be integrated into almost any location, they can be positioned to be easily accessible for the driver. Therefore, there is no need to remove a hand from the steering wheel in order to operate the control system. Preferably, at least one sensor electrode is disposed on the outer periphery of the steering wheel so that a user can activate the sensor electrode while keeping his hand on the outer periphery, thereby maintaining full control of the steering wheel.

It is preferred that at least one sensor electrode is disposed underneath a cover layer of the vehicle component (e.g. the steering wheel). This cover layer may be a plastic or leather lining that gives rise to a desirable haptic and/or optic characteristic of the vehicle component. While the sensor electrode remains hidden from view under the cover layer, it is also protected by the cover layer from mechanical damage. Furthermore, the cover layer helps to electrically isolate the respective sensor electrode. Optionally, the cover layer could be provided with visible or tactile markings that indicate the position of the sensor electrode, the gesture and/or its associated control signal.

It is highly desirable that the individual sensor electrode has a reduced thickness so it can be easily integrated into any part of the vehicle component without significantly influencing the outer dimensions of the vehicle component, e.g. the steering wheel. In this context it is highly preferred that at least one sensor electrode is a conductive foil electrode. The foil electrode is normally disposed parallel to the surface of the vehicle component. Since such a foil electrode may have a thickness that is negligible compared to the dimension of any typical vehicle component, it can be easily integrated into any surface, in particular underneath a cover layer as mentioned above. Also, a foil electrode is normally highly flexible which also facilitates integration into any kind of surface, e.g. a curved surface of an outer periphery of the vehicle component. The foil electrode could e.g. be made entirely of metal or could comprise a metal film on a plastic substrate.

According to one embodiment, the control unit is configured to identify at least one tapping gesture. Such a tapping gesture corresponds to the at least one body part (normally a hand or a finger) touching the surface of the vehicle component for a limited time interval. The tapping gesture could be a single tap or a multiple tap, i.e. a series of touching motions. The control unit may in particular be adapted to distinguish a single tap from a multiple tap or even different multiple taps (e.g. double tap and triple tap).

According to another embodiment, which may be combined with the above embodiment, the control unit is configured to identify at least one swiping gesture. Such a swiping gesture corresponds to a motion of the at least one body part along the surface of the vehicle component. Preferably, the control unit is configured to distinguish between different swiping gestures, which may differ by their direction or their speed. The swiping gesture could correspond e.g. to a linear motion or an arcuate motion.

According to a preferred embodiment, the control unit is adapted to identify a plurality of gestures based on the capacitance of a single sensor electrode. In other words, several gestures can be identified and distinguished based on the capacitance of a single sensor electrode. As will be explained below, this is normally achieved by a special geometry of the respective sensor electrode. However, different tapping gestures can normally be distinguished irrespective of the geometry of the sensor electrode.

On the one hand, it is clear that the control unit should be able to safely distinguish different gestures corresponding to different control signals. On the other hand, it is possible that the user performs some random motion, i.e. some motion that is not intended as an input to the control system. In many cases, such random motion is different from the predefined gestures, either differing by the direction of motion, the speed, the motion pattern or other parameters. According to a preferred embodiment, the control unit is configured to distinguish a gesture corresponding to a control signal from a random motion of the body part and to ignore the random motion. There are various possibilities how to distinguish gestures from random motion—and different gestures from each other. Such possibilities include application of a polynomial classifier and/or a support vector machine. In other words, the control unit can be configured to distinguish a gesture corresponding to a control signal from a random motion of the body part by applying a polynomial classifier and/or a support vector machine. A support vector machine could be programmed (or “trained”) before the vehicle is delivered. Alternatively or additionally it would be conceivable that the control unit is configured for a learning or training mode performed by the user, where the user performs certain gestures corresponding to control signals and the control unit learns to distinguish these gestures performed by this specific user.

Optionally, the control unit can be divided into several modules. These modules are preferably software-implemented and correspond to different algorithms or parts of an algorithm, but they could also correspond to physically distinct entities. According to one such an embodiment, the control unit comprises a measurement module, a signal process module and a gesture separation module. A signal representative of the capacity, which is measured and recorded by the measurement module, can be processed by the signal process module, which is responsible for signal feature computation, signal filtering and triggering the next module (i.e. the gesture separation module). The gesture separation module separates (intended) gestures from (unintended) random motion by means of a machine learning algorithm like Polynomial Classifier and/or Support Vector Machine (SVM) that has the signal features as its input.

According to one embodiment, at least one sensor electrode has a width that changes along a length of the sensor electrode. In this context, the width and the length of the sensor electrode are normally the dimensions with respect to two different directions along the surface of the vehicle component. In particular, these directions may be perpendicular to each other. However, they do not have to be straight with respect to a Cartesian coordinate system. For example, if the surface of the vehicle component is spherical, both directions normally would be curved, e.g. corresponding to the polar and azimuthal direction. However, even if the surface is plain, the directions on could e.g. correspond to a radial and tangential direction. In other words, the respective sensor electrode could be arcuate, i.e. extending along an arc, along which the length would be measured.

According to one embodiment, the width changes continuously along the length. It may change monotonously along the length, even in a linear way. This means that the width either decreases or increases along the entire length. For example, the respective sensor electrode could be triangular or trapezoidal. For example, if a body part is moved along the length of a triangular sensor electrode, the capacitance change is roughly proportional to the area of the sensor electrode that is covered by the body part. Therefore, it is possible to distinguish whether the body part is moved from the base to the tip of the triangle or in the opposite direction.

Alternatively or additionally to the above-mentioned continuous change, the width may change discontinuously along the length. In other words, the width changes stepwise. According to one example, the shape of the sensor electrode could correspond to two rectangles of different width put together. However, this concept could be varied by providing a plurality of stepwise changes. It is even conceivable to provide a characteristic sequence of portions having different width, so that the capacitance changes more or less corresponding to the same sequence if the body part is moved at a more or less constant speed along the length of the sensor electrode.

According to another embodiment, the control unit can be adapted to identify at least one gesture based on the capacitances of a plurality of sensor electrodes. For example, two or more sensor electrodes could be disposed along the surface of the vehicle component next to each other so that when the user performs a swiping gesture over these sensor electrodes, the capacitances of the sensor electrodes are changed one after another. Another possibility could be to distinguish a touch by a single finger (or maybe two fingers), e.g. corresponding to a tapping gesture, from a touch with the entire hand, which could correspond to the user touching the vehicle component without the intention to input a command. This could be distinguished by either a single capacitance being affected or a plurality of capacitances being affected.

It can also be advantageous if at least two sensor electrodes are disposed proximate to each other along the surface of the vehicle component, so that the capacitances of at least two sensor electrodes are influenceable simultaneously by a single body part. In other words, at least two sensor electrodes are disposed so close to each other that a single body part (in particular a hand or even a single finger) can be positioned so that the capacitances of both sensor electrodes are affected. In particular, this may include two sensor electrodes having an identical or similar length, wherein the width of one sensor electrode increases along the length, whereas the width of the other sensor electrode decreases. As a body part is placed at a specific position along the length, it changes the capacitance of both sensor electrodes locally, i.e. in the area where the body part is disposed adjacent the respective sensor electrode. Since the capacitance of a specific portion of an electrode is (more or less) proportional to the area of this portion, the change in capacitance depends on the width of the respective electrode this area. For example, in a position where the width of one electrode is relatively large while the width of the other electrode is relatively small, the proximity of the body part gives rise to a greater capacitance change for the first electrode than for the other electrode. Thus, by evaluating the ratio of capacitance changes for both sensor electrodes, the position of the body part along the length can be determined or estimated.

In general, identification of the at least one gesture is based on the capacitance of at least one sensor electrode. Since the gesture corresponds to a motion, the analysis has to take into account the time evolution of the capacitance. Usually, not the absolute capacitance is the relevant quantity, but rather the change of the capacitance with respect to a nominal value (or reference value), which may correspond to the capacitance when the body part of the user is not present. Preferably, in order to identify the at least one gesture, the control unit is configured to analyse an amplitude, a gradient, a duration and/or a time interval of a capacitance change with respect to a nominal value as a function of time. In other words, the control unit evaluates the capacitance change as a function of time, which normally includes recording the capacitance or the capacitance change at several points in time, possibly even continuously. As indicated above, it is also possible to evaluate a quantity that is representative of the capacitance. The amplitude may e.g. indicate of which part of an electrode the body part is positioned, if the electrode has a varying width over its length as described above. For example, if the width increases or decreases discontinuously, this can be identified by an abrupt increase or decrease in the amplitude. If a nonzero capacitance change occurs over a certain time interval, the duration can be used to identify a tapping gesture, where the duration should be rather short, e.g. less than 0.2 seconds. Also, a time interval between “pulses” of capacitance change can be used to distinguish a single tap from a double tap. For example, a double tap could only identified as such if the time interval is less than 1 second.

### BRIEF DESCRIPTION OF THE DRAWINGS

Further details and advantages of the present invention will be apparent from the following detailed description of not limiting embodiments with reference to the attached drawing, wherein:

FIG. 1 is a schematic view of an embodiment of the inventive control system;

FIG. 2 is a schematic view of a first sensor electrode;

FIG. 3 is a schematic view of a second sensor electrode;

FIG. 4 is a schematic view of a third sensor electrode;

FIG. 5 is a schematic view of a fourth and fifth sensor electrode;

FIG. 6 is a flowchart illustrating several steps of signal processing in the control system from FIG. 1;

FIG. 7 illustrates a first gesture by a user;

FIG. 8 illustrates a second gesture by user;

FIG. 9A illustrates a third gesture by a user;

FIG. 9B corresponds to a view along the direction IX B in FIG. 9A;

FIG. 10 shows a time evolution of a capacitance corresponding to the first gesture;

FIG. 11 shows a time evolution of the capacitance corresponding to the second gesture;

FIG. 12 shows a time evolution of the capacitance corresponding to the third gesture; and

FIG. 13 shows a time evolution of the capacitance corresponding to a fourth gesture.

### DESCRIPTION OF PREFERRED EMBODIMENTS

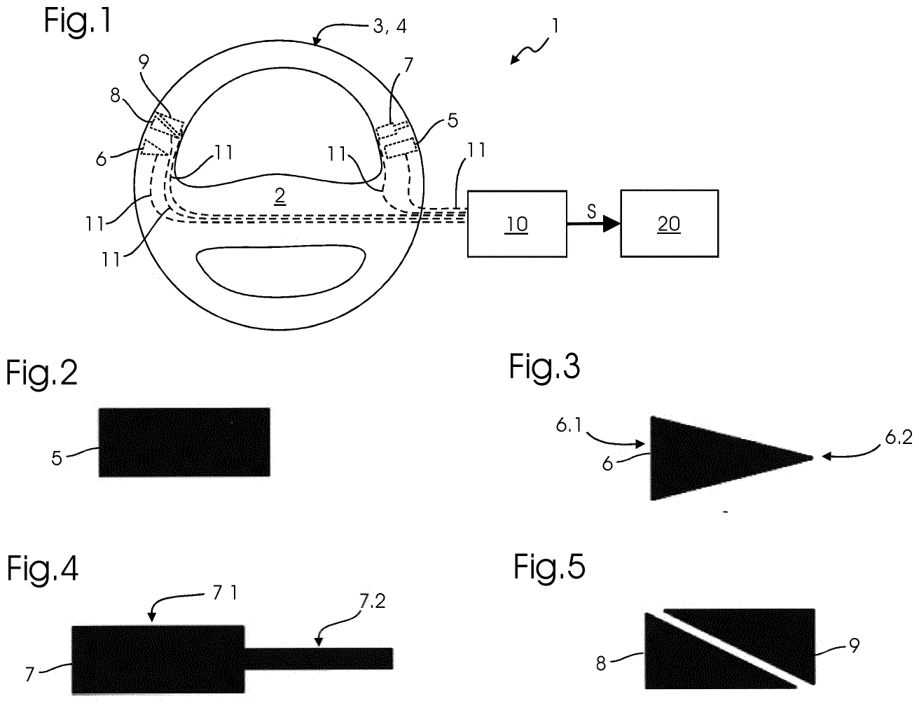

FIG. 1 schematically shows an inventive control system 1 for a vehicle, in this case for a passenger car. The control system 1 comprises a plurality of sensor electrodes 5-9 which are disposed on a steering wheel 2 of the vehicle. More specifically, the sensor electrodes 5-9 are disposed near the outer periphery of the steering wheel 2, underneath a surface 3 of the steering wheel 2. The surface 3 is covered by a cover layer 4, which may be made of leather, plastic or the like. The function of the cover layer 4 is to electrically isolate the sensor electrodes 5-9, to mechanically protect them and to provide favorable haptic properties for a user (i.e. the driver of the vehicle). The sensor electrodes 5-9 are conducting foil electrodes, which can be very thin, e.g. less than 0.2 mm, and highly flexible, wherefore they can be easily integrated in almost any location of the steering wheel 2 without (significantly) increasing the dimensions of the steering wheel 2. Each sensor electrode 5-9 is electrically connected to a control unit 10 by a conductor 11. The routing of the conductors 11 in FIG. 1 has been simplified and the position of the control unit 10 does not correspond to a realistic position with respect to the steering wheel 2.

The control unit 10 can apply an electrical signal to each of the sensor electrodes 5-9, e.g. a constant voltage or a sinusoidal voltage with a constant amplitude. Furthermore, the control unit 10 is configured to measure a quantity that is representative of the capacitance of the respective sensor electrode 5-9 with respect to the vehicle ground. Such a quantity could be the capacitance itself or, for example, a sinusoidal current flowing into the respective electrode 5-9, from which the capacitance could be calculated. As the electric signal is applied, each of the electrodes 5-9 generates an electric field above the surface 3. If an object like a hand 40 of the user enters the electric field, the electric field and the capacitance of the sensor electrode 5-9 is changed.

Furthermore, the capacitance depends on the position of the hand 40 with respect to the steering wheel 2 and the respective sensor electrode 5-9. Therefore, if the position of the hand 40 changes over time, the same applies to the capacitance. A motion of the hand 40 may correspond to a predefined gesture G₁-G₃ by which the user may control a vehicle system 20, e.g. an infotainment system, a communication system a navigation system, an air-conditioning system or the like. The respective gesture G₁-G₃ is performed on the outer periphery of the steering wheel 2, wherefore the user can keep his hand 40 on the steering wheel, thereby maintaining full control of the vehicle. The control unit 10 is configured to identify the gesture G₁-G₃ and the corresponding control signal S. When the control signal S has been identified, it is output by the control unit 10 to the vehicle system 20. It is understood that the control signal S can be an analogue signal or, in particular, a digital signal.

FIGS. 2 to 5 show different embodiments of sensor electrodes 5-9 that can be used in the control system 1. Normally, not all of these embodiments would be used on a single steering wheel 2, as shown in FIG. 1. Rather, FIG. 1 is to be understood as illustrating different possibilities for the electrode layout. FIG. 2 shows a first sensor electrode 5 which has a rectangular shape. With this design, it is normally not possible to identify a swiping gesture G₁, G₂, but a tapping gesture G₃ (as shown in FIG. 9) can be identified by the time evolution of the capacitance. During a tapping gesture G₃, the hand 40 (or one or several fingers) of the user quickly approaches the sensor electrode 5, remains in the proximity of the sensor electrode 5 for a short time interval and is afterwards quickly removed. This gives rise to a capacitance change (with respect to a nominal value of the capacitance) that has a high gradient and a short duration (as shown in FIGS. 12 and 13, the latter of which shows a double tap).

FIG. 3 shows a second sensor electrode 6 with a triangular shape. In other words, a width of the sensor electrodes 6 decreases linearly along its length from a first end 6.1 to a second end 6.2. Of course, it is also possible to identify a tapping gesture G₃ with this second sensor electrode 6. Furthermore, it is conceivable to identify a swiping gesture G₁, G₂, where the user moves his hand 40 (or finger(s)) over the length of the sensor electrode 6 from the first end 6.1 to the second end 6.2 or vice versa. This is because the capacitance change is roughly proportional to the area of the sensor electrode 6 that is covered by the hand 40. Therefore, the capacitance change is largest when the hand 40 is positioned over the first end 6.1 and smallest when the hand 40 is positioned over the second end 6.2. In general, a swiping gesture G₁, G₂ could be identified by a gradient of the capacitance change (corresponding to the motion of the hand 40 over the length of the sensor electrode 6) and possibly by its duration. For instance, the swiping gesture G₁, G₂ should be performed in a time interval between e.g. 0.2 seconds and 2 seconds. If the duration of the capacitance change is shorter or longer, the corresponding hand movement is not identified as a swiping gesture G₁, G₂, but e.g. as a random motion performed by the user. If such a random motion is identified, it is ignored by the control unit 10. By applying various criteria, the control unit 10 may not only distinguish different gestures G₁-G₃ but also distinguish random motion from a gesture G₁-G₃ intended as an input to the control system 1. All this can be achieved by measuring and analysing the capacitance of a single sensor electrode 5-9.

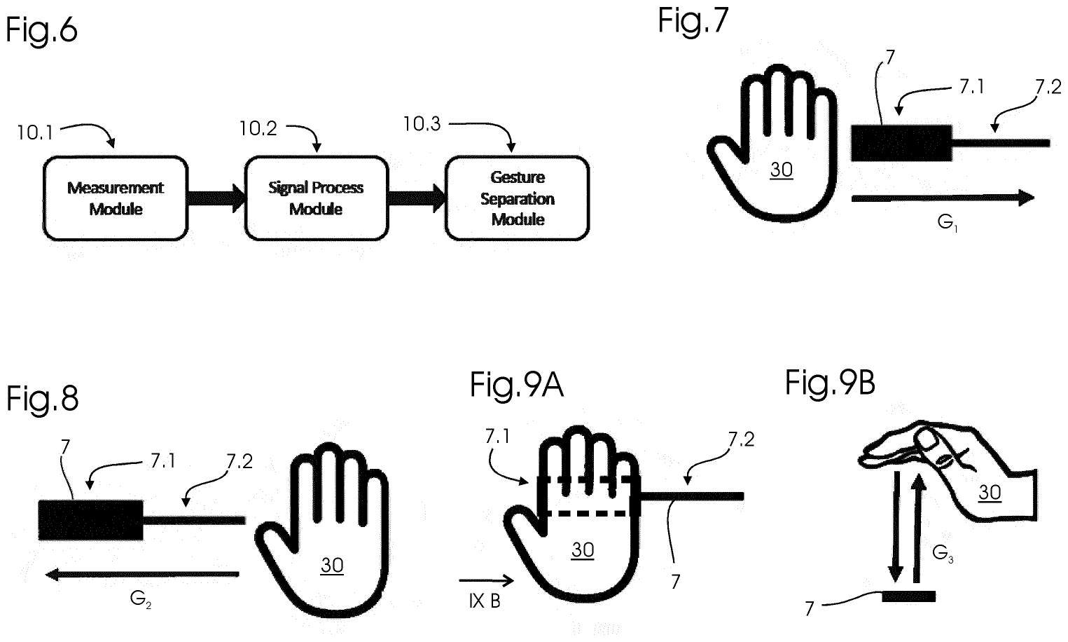

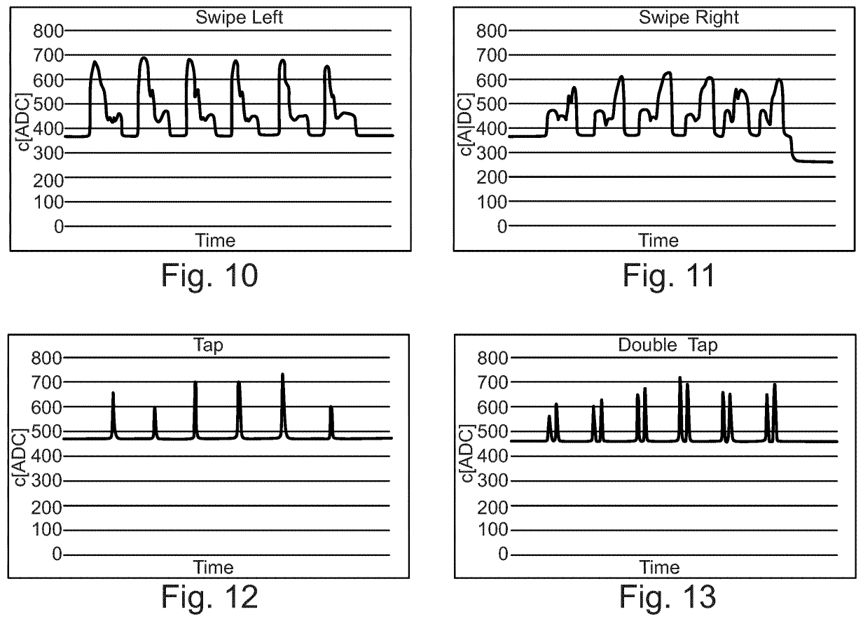

While FIG. 3 shows a sensor electrode 6 where the width changes continuously over its length, FIG. 4 shows a third sensor electrode 7 having a width that changes discontinuously or stepwise over its length. The third sensor electrode 7 comprises a first portion 7.1 having a larger width and a second portion 7.2 having a smaller width. If the hand 40 is positioned adjacent the first portion 7.1, the capacitance change with respect to a nominal value (corresponding to the absence of the hand 40) is larger than if the hand 40 is positioned adjacent the second portion 7.2. Therefore, if the user performs a series of swiping gestures G₁ from left to right as illustrated in FIG. 7, this gives rise to a time evolution of the capacitance as shown in FIG. 10. Measurement of the capacitance can be performed by a measurement module 10.1 of the control unit 10 as shown in the flowchart of FIG. 6. The “raw” signal as shown in FIG. 10 is further processed by the signal processing module 10.2, which can perform a signal feature computation (e.g. to determine a gradient, a duration, and amplitude and/or a time interval between consecutive signals) and signal filtering (e.g. to remove noise). The determined features can then be forwarded to a gesture separation module 10.3, which differentiates between different gestures G₁-G₃ and also between (intended) gestures and random motion. This may be achieved by applying a polynomial classifier and/or a support vector machine. A support vector machine could be programmed (or “trained”) before the vehicle is delivered. Alternatively or additionally it would be conceivable that the control unit 10 is configured for a learning or training mode performed by the user, where the user performs certain gestures G₁-G₃ corresponding to control signals S and the control unit 10 learns to distinguish these gestures G₁-G₃ performed by this specific user.

FIG. 8 illustrates a swiping gesture G₂ from right to left. The corresponding time evolution of the capacitance is shown in FIG. 11 for a sequence of consecutive swiping gestures G₂. By comparing the FIG. 10 and FIG. 11, it is evident that as swiping from left to right is performed, the capacitance change starts with a high amplitude as the hand 40 is placed over the first portion 7.1 and continues with the drop to a low amplitude as the hand 40 reaches the second portion 7.2. On the other hand, as swiping from right to left is performed, the capacitance change starts with a comparatively low amplitude, which abruptly increases as the hand 40 is moved from the second portion 7.2 to the first portion 7.1.

FIGS. 9A and 9B illustrate a tapping gesture G₃, where the hand 40 quickly approaches the sensor electrode 7 (e.g. the first portion 7.1), remains adjacent the sensor electrode 7 for a very short time interval and then quickly moves away. As shown in FIG. 12, each tap gives rise to a very short pulse in the capacitance change, which can be clearly distinguished from the swiping gestures G₁, G₂ of FIGS. 10 and 11. FIG. 13 shows the time evolution of the capacitance for a sequence of double taps, which give rise to pairs of short pulses.

While it is possible to identify a gesture G₁-G₃ by analysing the capacitance of a single sensor electrode 5-9, the control unit 10 may also identify a gesture G₁-G₃ based on the capacitances of a plurality of sensor electrodes 5-9. FIG. 5 shows a configuration where a fourth sensor electrode 8 and fifth sensor electrode 9 are disposed proximate to each other. Each sensor electrode 8, 9 is triangular in shape. While the width of the fourth sensor electrode 8 decreases along its length, the width of the fifth sensor electrode 9 increases. Since these two electrodes 8, 9 are positioned closely together, there capacitances can be influenced simultaneously by the hand 40 or even a single finger. As the respective body part is moved e.g. from left to right, the capacitance change of the fourth sensor electrode 8 decreases while the capacitance change of the fifth sensor electrode 9 increases at the same time. By comparing the capacitance changes of both sensor electrode 8, 9 it is possible to determine the current position of the body part with higher accuracy, since the ratio of the capacitance changes is more or less independent of the size of the body part and its distance from the sensor electrodes 8, 9.

1. A control system for a vehicle, comprising:
at least one sensor electrode disposed on an vehicle component with a surface accessible to a user, the sensor electrode being adapted to generate an electric field above the surface so that a capacitance of the sensor electrode depends on a position of a body part of a user with respect to the vehicle component, and
a control unit connected to the at least one sensor electrode and adapted to:
identify at least one gesture, corresponding to a motion of the body part with respect to the vehicle component, based on the capacitance of the at least one sensor electrode,
identify a control signal for the vehicle that corresponds to the gesture; and
output the control signal,
wherein at least one sensor electrode has a first portion and a second portion wherein the capacitance depends on whether the body part is disposed adjacent the first portion or the second portion.

2. The control system according to claim 1, wherein the vehicle component is a steering wheel.

3. The control system according to claim 2, wherein at least one sensor electrode is disposed underneath a cover layer of the vehicle component.

4. The control system according to claim 1, wherein at least one sensor electrode is a conductive foil electrode.

5. The control system according to claim 1, wherein the control unit is adapted to identify a plurality of gestures based on the capacitance of a single sensor electrode.

6. The control system according to claim 1, wherein the control unit is configured to identify at least one tapping gesture.

7. The control system according to claim 1, wherein the control unit is configured to identify at least one swiping gesture.

8. The control system according to claim 1, wherein the control unit is configured to distinguish a gesture corresponding to a control signal from a random motion of the body part and to ignore the random motion.

9. The control system according to claim 1, wherein the control unit is configured to distinguish a gesture corresponding to a control signal from a random motion of the body part by applying a polynomial classifier and/or a support vector machine.

10. The control system according to claim 1, wherein at least one sensor electrode has a width that changes along a length of the sensor electrode.

11. The control system according to claim 1, wherein the width changes continuously along the length.

12. The control system according to claim 1, wherein the width changes discontinuously along the length.

13. The control system according to claim 1, wherein the control unit is adapted to identify at least one gesture based on the capacitances of a plurality of sensor electrodes.

14. The control system according to claim 1, wherein at least two sensor electrodes are disposed proximate to each other along the surface of the vehicle component so that the capacitances of at least two sensor electrodes are influenceable simultaneously by a single body part.

15. The control system according to claim 1, wherein in order to identify the at least one gesture and, the control unit is configured to analyse an amplitude, a gradient, a duration and/or a time interval of a capacitance change with respect to a nominal value as a function of time.
